(19) United States
(12) Patent Application Publication
(10) Pub. No.: US 2021/0335685 A1
(43) Pub. Date: Oct. 28, 2021

(54) MOISTUREPROOFING CHIP ON FILM PACKAGE

(71) Applicant: Silicon Works Co., Ltd., Daejeon (KR)

(72) Inventors: Dam HA, Daejeon (KR); Kyung Hyun KIM, Daejeon (KR)

(73) Assignee: Silicon Works Co., Ltd., Daejeon (KR)

(21) Appl. No.: 17/238,646

(22) Filed: Apr. 23, 2021

(30) Foreign Application Priority Data
Apr. 27, 2020 (KR) 10-2020-0050644

(51) Int. Cl. H01L 23/31; H01L 23/29; H01L 23/00

(52) U.S. Cl. CPC H01L 23/3135; H01L 23/293; H01L 23/4985; H01L 24/73; H01L 23/564; H01L 23/3185

(57) ABSTRACT

The present disclosure discloses a moistureproofing chip on film (COF) package for protecting the conductive pattern of the COF package against moisture. The moistureproofing COF package includes a base film having a conductive pattern formed on one surface thereof and having a solder resist formed on the conductive pattern and a moistureproofing tape attached to the top of the solder resist and configured to block moisture from being delivered to the conductive pattern through the solder resist.

### BACKGROUND

### 1. Technical Field

The present disclosure relates to a chip on film package (hereinafter referred to as a “COF package”), and more particularly, to a moistureproofing COF package for protecting a conductive pattern of the COF package against moisture.

### 2. Related Art

A display device includes a display panel, such as an LCD panel or an LED panel, and a driver integrated circuit for processing display data.

Of them, the driver integrated circuit is configured to process display data provided from the outside and to provide the display panel with an image signal corresponding to the display data. The display panel may display a screen based on the image signal of the driver integrated circuit.

In general, the driver integrated circuit is fabricated in the form of a COF package and mounted on the display panel.

The driver integrated circuit fabricated in the form of the COF package is commonly used without processing for moistureproofing. Furthermore, a solder resist applied on the COF package in order to protect a conductive pattern thereof has a low moistureproofing effect.

Accordingly, if the COF package is used in a high humidity environment, such as a vehicle, moisture may penetrate into the conductive pattern of the COF package through the solder resist. As a result, an electrical failure such as a short-circuit attributable to an action, such as an ion migration, may occur in the conductive pattern of the COF package.

Accordingly, the COF package including the driver integrated circuit needs to be configured to have a moistureproofing function in order to improve product reliability.

### SUMMARY

Various embodiments are directed to providing a moistureproofing COF package using a moistureproofing tape.

Also, various embodiments are directed to preventing an electrical failure such as a short-circuit, which may occur in a conductive pattern due to the penetration of moisture through a solder resist.

Furthermore, various embodiments are directed to providing a moistureproofing COF package capable of preventing the penetration of moisture into a semiconductor chip and a solder resist or the solder resist.

In an embodiment, a moistureproofing COF package may include a base film having a conductive pattern formed on one surface thereof and having a solder resist formed on the conductive pattern and a moistureproofing tape attached to the top of the solder resist and configured to block moisture from being delivered to the conductive pattern through the solder resist.

According to the present disclosure, the COF package can have a moistureproofing function by finishing the COF package by using the moistureproofing tape.

Furthermore, the moistureproofing COF package of the present disclosure can prevent an electrical failure such as a short-circuit, which may occur in the conductive pattern under the solder resist, by preventing the penetration of moisture through the solder resist.

Furthermore, the moistureproofing COF package of the present disclosure can provide improved product reliability by preventing the penetration of moisture into a chip and the solder resist or the solder resist.

### BRIEF DESCRIPTION OF THE DRAWINGS

FIG. 1 is a side view illustrating a preferred embodiment of a moistureproofing COF package according to the present disclosure.

FIG. 2 is a cross-sectional view illustrating an example of a moistureproofing tape of FIG. 1.

FIG. 3 is a cross-sectional view illustrating another example of the moistureproofing tape of FIG. 1.

FIG. 4 is a side view illustrating another embodiment of the present disclosure.

### DETAILED DESCRIPTION

Exemplary embodiments will be described below in more detail with reference to the accompanying drawings. The disclosure may, however, be embodied in different forms and should not be constructed as limited to the embodiments set forth herein. Rather, these embodiments are provided so that this disclosure will be thorough and complete, and will fully convey the scope of the disclosure to those skilled in the art. Throughout the disclosure, like reference numerals refer to like parts throughout the various figures and embodiments of the disclosure.

An embodiment of the present disclosure discloses a driver integrated circuit fabricated in the form of a COF package. The driver integrated circuit fabricated in the form of a semiconductor chip is mounted on the COF package. The COF package according to an embodiment of the present disclosure is configured to have a moistureproofing function.

The present disclosure is carried out to implement the moistureproofing function by using a moistureproofing tape. The COF package having the moistureproofing function according to the present disclosure is referred to as a “moistureproofing COF package.”

The moistureproofing COF package of the present disclosure has the driver integrated circuit, that is, the semiconductor chip mounted thereon. The semiconductor chip is configured to be supplied with external display data and power and to provide an image signal to a display panel, such as an LCD panel or an LED panel.

The moistureproofing COF package implemented according to an embodiment of the present disclosure is configured to be supplied with the display data and power through a conductive pattern or to supply an image signal to the display panel.

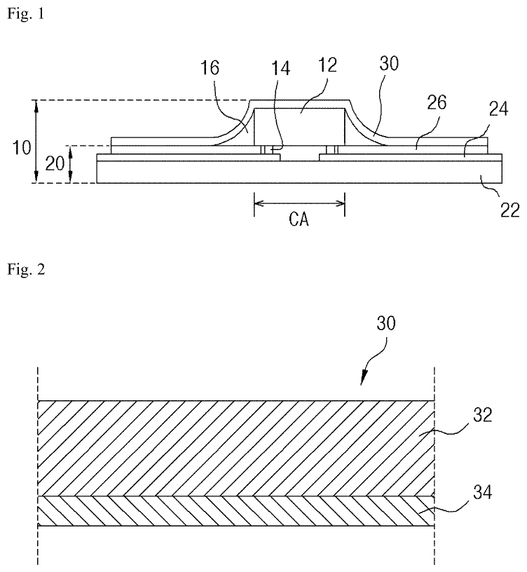

Referring to FIG. 1, a moistureproofing COF package 10 according to the present disclosure includes a base film 20 and a moistureproofing tape 30.

The base film 20 includes a conductive pattern 24 and a solder resist 26 on one surface thereof. The solder resist 26 is formed on the conductive pattern 24.

Furthermore, a semiconductor chip 12 is mounted on the one surface of the base film 20. The semiconductor chip 12 may be understood as the driver integrated circuit as described above.

The semiconductor chip 12 includes input pads (not illustrated) for receiving display data and a voltage from the outside and output pads (not illustrated) for outputting source signals and a voltage to a display panel (not illustrated).

The input pads and the output pads may be arranged in side parts facing each other at the bottom of the semiconductor chip 12. Bumps 14 are configured in the input pads and the output pads, respectively. The bumps 14 may be understood as soldering terminals formed for an electrical connection with ends of the conductive pattern 24, which form a routing line on the base film 20.

The base film 20 has a film 22 made of polyimide. The film 22 may have flexibility according to characteristics of a material.

In the base film 20, the conductive pattern 24 is formed on one surface of the film 22. The conductive pattern 24 may be understood as forming routing lines for the input and output of a signal and the supply of power. That is, the conductive pattern 24 may be understood as the routing lines.

A chip area CA in which the semiconductor chip 12 is disposed may be configured in the one surface of the film 22. If the semiconductor chip 12 is disposed in the chip area CA, the bumps 14 may be located within the chip area CA on the one surface of the film 22.

The conductive pattern 24 for routing is formed on the one surface of the film 22 so that the conductive pattern 24 has a preset pattern formed of a thin film for an electrical connection between the semiconductor chip 12 and the display panel (not illustrated).

The conductive pattern 24 has one end extended into the chip area CA for a contact with the bumps 14. Furthermore, the conductive pattern 24 has the other end extended into the side parts of the film 22 for an electrical connection with the display panel. The conductive pattern 24 may be made of a conductive material, such as copper (Cu).

By means of the conductive pattern 24, the bumps 14 of the semiconductor chip 12 may be electrically connected to corresponding ends of the conductive pattern 24 extended into the chip area CA, respectively.

The solder resist 26 is applied on the conductive pattern 24.

The solder resist 26 is formed outside the bumps 14 of the chip area CA, and is applied over the conductive pattern 24 and the film 22 in a way to form a layer. The solder resist 26 is preferably applied so that one end and the other end of the pattern 24 where electrical connections are performed are exposed.

The solder resist 26 configured as described above may be understood as a coating layer playing a role as a protection film for protecting the conductive pattern 24. For example, the solder resist 26 may be formed by the application of ink having an insulating property.

The semiconductor chip 12 is mounted on the one surface of the base film 20. A potting resin 16 may be formed on the side of the semiconductor chip 12. The potting resin 16 is preferably formed to surround the side of the semiconductor chip 12. Accordingly, the potting resin 16 may be understood as being configured to prevent moisture from penetrating through a gap between a lower part of the side of the semiconductor chip 12 and the solder resist 26 and to firmly fix the semiconductor chip 12.

An embodiment of the present disclosure includes the moistureproofing tape 30. The moistureproofing tape 30 may be attached to the top of the solder resist 26 as illustrated in FIG. 1. The moistureproofing tape 30 is configured to cover the top of the solder resist 26, and blocks moisture from being delivered to the solder resist 26. As a result, the moistureproofing tape 30 has a function for blocking moisture from being delivered to the conductive pattern 24 through the solder resist 26.

To this end, the moistureproofing tape 30 may be configured using a moistureproofing-possible material. The moistureproofing-possible material may be one of poly cyclohexylenedimethylene terephthalate (PCT), casting polypropylene (CPP), polyethylene terephthalate (PET), and polyimide (PI).

Referring to FIG. 2, the moistureproofing tape 30 may be configured to have a structure in which a base 32 and an adhesive layer 34 are stacked.

The base 32 may be understood as a moistureproofing layer formed of a thin film, having one of the PCT, CPP, PET and PI materials, as described above.

The adhesive layer 34 is formed at the bottom of the base 32, and is configured to provide an adhesive force for adhesion between the base 32 and the solder resist 26 of the base film 20.

By means of the construction, the moistureproofing tape 30 may be attached to the top of the solder resist 26 of the base film 20 by the adhesive force of the adhesive layer 34.

Accordingly, the moistureproofing COF package of the present disclosure using the moistureproofing tape 30 having a structure illustrated in FIG. 2 can use the moistureproofing function of the moistureproofing tape 30 so as to prevent moisture from being delivered to the solder resist 26. As a result, an electrical failure such as a short-circuit, which may occur in the conductive pattern 24, can be prevented by preventing the penetration of moisture through the solder resist 26.

Furthermore, the moistureproofing tape 30 may be configured to further include a coating layer 36 as illustrated in FIG. 3.

The coating layer 36 may have the same area and shape as the base 32, and is configured to cover the top of the base 32.

The coating layer 36 may impart various functionalities to the moistureproofing tape 30 depending on a material.

For example, if the coating layer 36 is made of a material having a moistureproofing power, the moistureproofing tape 30 may have a reinforced moistureproofing power. In this case, the coating layer 36 may be made of a moistureproofing material identical with or different from that of the base 32.

Furthermore, if the coating layer 36 is made of a colorful material having legibility which can be easily distinguished visually, the moistureproofing tape 30 may have legibility. That is, the moistureproofing COF package implemented according to an embodiment of the present disclosure can be easily distinguished from other parts by the legibility of the moistureproofing tape 30.

Furthermore, the coating layer 36 is formed to have a predetermined thickness, and thus may be understood as having a function for protecting an appearance of the moistureproofing tape 30.

In an embodiment of the present disclosure, the moistureproofing tape 30 may be configured to have an area capable of covering the chip 12 and the solder resist 26 as illustrated in FIG. 1.

In this case, the moistureproofing tape 30 can block moisture from being delivered to the chip 12 in addition to the solder resist 26.

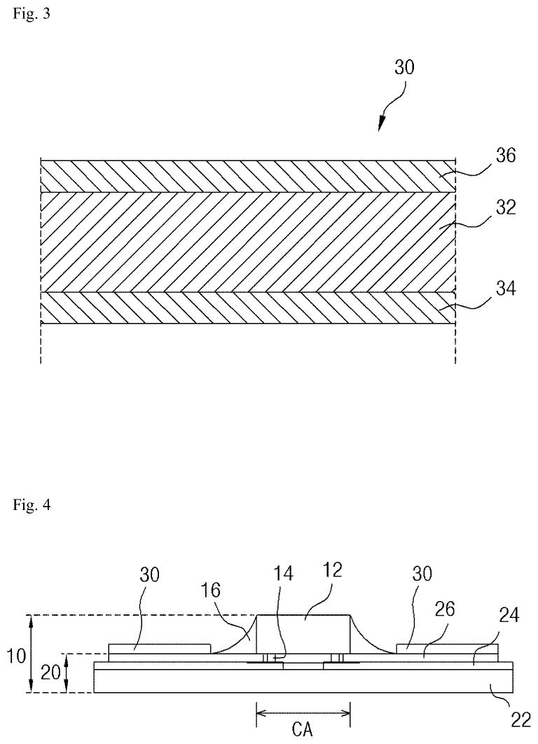

Furthermore, in an embodiment of the present disclosure, the moistureproofing tape 30 may be configured to cover an area restricted by the top of the solder resist 26 as illustrated in FIG. 4.

In this case, the moistureproofing tape 30 can block moisture from being delivered to the solder resist 26.

Accordingly, the present disclosure can implement the moistureproofing COF package by using the moistureproofing tape, and can prevent the penetration of moisture through the solder resist because the moistureproofing tape can block moisture from being delivered to the solder resist, that is, an underlying layer.

Accordingly, the present disclosure can prevent an electrical failure, such as a short-circuit, which may occur in the conductive pattern under the solder resist due to moisture.

Furthermore, the present disclosure can provide improved product reliability by preventing the penetration of moisture into the chip and the solder resist or the solder resist.

While various embodiments have been described above, it will be understood to those skilled in the art that the embodiments described are by way of example only. Accordingly, the disclosure described herein should not be limited based on the described embodiments.

What is claimed is:

1. A moistureproofing chip on film (COF) package comprising:
a base film having a conductive pattern formed on one surface thereof and having a solder resist formed on the conductive pattern; and
a moistureproofing tape attached to the top of the solder resist and configured to block moisture from being delivered to the conductive pattern through the solder resist.

2. The moistureproofing COF package of claim 1, wherein the moistureproofing tape uses one of poly cyclohexylenedimethylene terephthalate (PCT), casting polypropylene (CPP), polyethylene terephthalate (PET), and polyimide (PI) as a base.

3. The moistureproofing COF package of claim 1, wherein the moistureproofing tape comprises:
a base; and
an adhesive layer formed under the base and configured to attach the base to a top of the base film.

4. The moistureproofing COF package of claim 3, wherein the moistureproofing tape further comprises a coating layer configured to cover the top of the base.

5. The moistureproofing COF package of claim 4, wherein the coating layer is made of a material having a moistureproofing power.

6. The moistureproofing COF package of claim 5, wherein the coating layer is made of the material identical with a material of the base.

7. The moistureproofing COF package of claim 1, wherein:
a semiconductor chip electrically connected to the conductive pattern is mounted on the one surface of the base film, and
the moistureproofing tape is formed to cover the semiconductor chip and the solder resist.

8. The moistureproofing COF package of claim 7, wherein:
a potting resin is further formed on a side of the semiconductor chip, and
the potting resin surrounds the semiconductor chip and fixes the semiconductor chip.

9. The moistureproofing COF package of claim 1, wherein the moistureproofing tape is formed to cover an area restricted by the top of the solder resist.
